(19) United States
(12) Patent Application Publication
(10) Pub. No.: US 2025/0137116 A1
(43) Pub. Date: May 1, 2025

(54) DEPOSITION SYSTEM AND METHOD FOR DISPLAY APPARATUS

(71) Applicant: Samsung Display Co., LTD., Yongin-si (KR)

(72) Inventors: Jaewan SEOL, Yongin-si (KR); Intaek YOON, Yongin-si (KR); Jongwook CHAE, Yongin-si (KR); Jonghyun CHOI, Yongin-si (KR)

(21) Appl. No.: 18/820,676

(22) Filed: Aug. 30, 2024

(30) Foreign Application Priority Data
Oct. 25, 2023 (KR) 10-2023-0143976

(51) Int. Cl. C23C 14/58; C23C 14/04; C23C 14/24; H10K 71/16

(52) U.S. Cl. CPC C23C 14/5806; C23C 14/042; H10K 71/164; C23C 14/24

(57) ABSTRACT

A deposition method for a display device includes continuously performing operations on at least two substrates arranged in a linear form in a process chamber. The operations include measuring a temperature of a surrounding area of a substrate while heating a deposition source of the deposition source device to a deposition-capable temperature in a deposition standby section, determining a heat influence distribution on the substrate or a mask based on measurement results provided by the heat distribution measurement unit, designing a cooling unit on top of the substrate or the mask in association with reducing the heat influence distribution on the substrate or the mask, installing or controlling the cooling unit in association with reducing the heat influence distribution, and performing a thin film deposition operation on the substrate while moving the deposition source device from the deposition standby section to a deposition area section.

This application claims priority to Korean Patent Application No. 10-2023-0143976, filed on Oct. 25, 2023, and all the benefits accruing therefrom under 35 U.S.C. § 119, the content of which in its entirety is herein incorporated by reference.

### BACKGROUND

### (a) Field

Embodiments of the present disclosure relate to a deposition system and method for a display device, and more specifically, to a deposition system and method for a display device including a cooling device for a deposition chamber, in which the deposition system and method support lowering the temperature of a display substrate or deposition mask in an in-line type deposition device.

### (b) Description of the Related Art

Research on organic light emitting diodes is ongoing in response to recent demands and needs for miniaturization, slimming, and high integration and various application fields of electrical and electronic products.

Unlike existing liquid crystal displays, some organic light emitting devices may be implemented without a backlight device and may emit light on their own. Accordingly, for example, organic light emitting devices may be lightweight and ultra-thin, consume low amounts of power, have a simplified structure supportive of reduced manufacturing complexity and increased manufacturing convenience, and be economically efficient. Due to their advantages, organic light emitting devices are receiving particular attention as next-generation display devices.

In some approaches, manufacturing such organic light emitting devices may include many manufacturing steps. Recently, research has been done on in-line deposition systems that may deposit organic films and metal films on the upper layer of the substrate while allowing linear or point evaporation sources to pass at a constant speed inside a process chamber arranged at specific intervals.

In particular, each process chamber may be generally equipped with a deposition source device including a crucible and a heating unit such as, for example, a heater. In an example in which a deposition source is placed inside the crucible and the crucible is heated by the heating unit, the deposition source material inside may evaporate and vaporize in response to the heat and be deposited on the substrate located on the opposite side.

Here, the heating provided by the heater in association with heating the crucible is high enough to vaporize the deposition source inside the crucible, and the heat is transferred to the substrate located on the opposite side of the crucible, causing damage and deformation of the substrate. Not only may defects in a thin film increase, but there is a problem in that the thin film may not be properly implemented when deposited at a specific thickness. To solve this problem, in some past approaches, a shield plate was placed between the crucible and the substrate or attached to the heater area on the top of the crucible to prevent the transfer of the heat from the heater to the substrate/mask.

However, for cases in which the length of the deposition shield plate is relatively long, not only may the deposition shield plate bend due to heat, but there is a problem in that the heat blocking effect of the deposition shield plate may be insufficient for cases in which the deposition shield plate is relatively thin.

Korea Intellectual Property Office Publication No. 10-2011-0032695, “Induction Heating Metal Deposition Source,” offers an improved technology. In the technology, a cooling shield is formed adjacent to the opening of the crucible and on the upper side of the heating unit, which includes a heater block with a built-in heater coil. The cooling shield blocks the high heat of the crucible caused by the heating unit from being transferred directly to the substrate/mask, which may prevent damage to the substrate.

However, in some cases, the method may be disadvantageous in that the heat blocking effect may be insufficient due to the use of a single plate, and the heat blocking effect may be inefficient due to the bending phenomenon of the cooling shield at high temperatures.

In some aspects, the above described technology is disadvantageous in that the cooling shield is in direct contact with the upper side of the heating unit, such that the heat from the heating unit is transferred directly to the cooling shield, and the heat blocking effect on the substrate/mask is insufficient (e.g., below a threshold value).

### SUMMARY

In association with solving the described problems, embodiments of the present disclosure reduce the temperature of the substrate/mask compared to before, improve thermal expansion of the substrate/mask, and enable the use of higher resolution masks than currently available, and the embodiments of the present disclosure support the production of a high-resolution product.

In association with solving the described problems, embodiments of the present disclosure reduce the temperature of the substrate/mask compared to the other approaches, which supports reducing the distance between the substrate and the deposition source, thereby improving deposition material efficiency and allowing for reduced production costs.

According to an embodiment supported by the present disclosure, a deposition system for a display device in which a process is continuously performed on at least two substrates arranged in a linear form in a process chamber including a deposition source device for thin film deposition, the process chamber including a deposition area section and a deposition standby section disposed between the deposition area sections, wherein the deposition source device is movably installed between the deposition area sections, and a substrate stage on which a substrate is installed above the deposition area section, it is arranged in a linear form and includes a deposition prevention unit disposed between the deposition source device and a substrate installed on the substrate stage, and a cooling unit that is interlocked with the deposition prevention unit and is directly coupled to the periphery of the substrate and protrudes upward.

A heat effect distribution measurement unit that is closely coupled to the substrate or substrate and measures the heat effect distribution around the mask while raising the deposition source to a deposition-capable temperature in the deposition source device, and the heat effect distribution measurement unit may include a cooling control device configured to control the deposition prevention unit or the cooling unit depending on the influence distribution.

According to an embodiment supported by the present disclosure, the deposition method for a display device in which a process is continuously performed on at least two substrates arranged in a linear form in a process chamber includes a deposition source device for thin film deposition, measuring the temperature of the surrounding area of the substrate with a heat distribution measurement unit while heating the deposition source to a deposition-capable temperature in the deposition waiting area, and determining the heat influence distribution on the substrate or mask according to the measurement results of the heat distribution measurement unit, a step of designing a cooling unit on top of the substrate or mask to reduce the heat influence distribution on the substrate or mask, installing or controlling the cooling unit to reduce the heat influence distribution, and performing thin film deposition on the substrate while moving the deposition source device from the deposition standby section to the deposition area section.

A deposition method for a display device according to an embodiment of another aspect supported by the present disclosure includes the steps of arranging a deposition source device between deposition tables in a process chamber and heating the temperature the deposition source device to a deposition temperature at which deposition is possible, and a step of fixing and installing a substrate on a substrate stage above the deposition source device, measuring a heat influence distribution around the substrate or a lower mask of the substrate, and a cooling unit in thermal contact with the substrate or the lower mask of the substrate, a step of performing a heat effect distribution offset cooling design with respect to the heat effect distribution, and performing a thin film deposition process by driving the deposition source device on the substrate or the lower mask of the substrate.

The heat effect distribution measurement unit may be a thermal imaging camera or a temperature sensor that measures the representative temperature of the area with the highest temperature in the deposition area among the substrate or the mask periphery.

In the step of performing the heat effect distribution offset cooling design, the cooling plate of the cooling unit may be formed as a barrier such that the cooling plate of the cooling unit protrudes upward at an angle of 90 degrees or more on all sides of the substrate or mask.

It may include moving the cooling plate of the cooling unit along the linear movement direction of the deposition source device, and selectively controlling the supply of coolant flowing to a local cooling pipe installed inside the cooling plate.

The deposition source device performs deposition on the substrate by alternately moving back and forth between the deposition area section and the deposition standby section formed at both edges of the deposition area section, and when the substrate is processed more than a predetermined number of times, the deposition source device may be powered off for temperature reset during the deposition standby period.

According to the deposition system and method as described herein for a display device, the system and method supports reducing the temperature of the substrate/mask compared to other approaches, which may improve the thermal expansion of the substrate/mask. Accordingly, for example, the system and method support using a higher resolution mask compared to some other approaches (e.g., a higher resolution mask than currently available), and accordingly, the production of a high-resolution product. According to the deposition system and method as described herein for a display device, the system and method supports reducing the temperature of the substrate/mask compared to other approaches, which may support reducing the distance between the substrate and the deposition source, thereby improving deposition material efficiency. Accordingly, for example, the system and method described herein support reductions in production cost.

### BRIEF DESCRIPTION OF THE DRAWINGS

FIG. 1 is a schematic perspective view of main parts of a conventional display device deposition system for suppressing increases in substrate/mask temperature.

FIG. 2 is a schematic perspective view illustrating a deposition system for a display device according to an embodiment supported by the present disclosure.

FIG. 3 is a cross-sectional view taken along line A-A of FIG. 2 and a diagram illustrating the temperature distribution in the adjacent portion of the substrate.

FIG. 4 is a plan view of FIG. 2 illustrating a method of operating a main part of a deposition system for a display device according to an embodiment supported by the present disclosure.

FIG. 5 is a detailed view of the main part of FIG. 2.

FIGS. 6 and 7 are diagrams illustrating the cooling improvement effect in substrate stages A and B, respectively, of the deposition system of the display device according to an embodiment supported by the present disclosure.

FIG. 8 is a perspective view of a deposition system for a display device according to a modified example of an embodiment supported by aspects of the present disclosure.

FIG. 9 is a diagram illustrating the structure of the cooling plate of FIG. 8.

FIG. 10 is a flowchart of a deposition method for a display device according to an embodiment supported by the present disclosure.

FIG. 11 is a plan view and a cross-sectional view of a display device manufactured using a deposition system and method according to an embodiment supported by the present disclosure.

### DETAILED DESCRIPTION

Hereinafter, example embodiments supported by aspects of the present disclosure will be described with reference to the drawings.

However, the following embodiments and examples described herein include example configurations and do not limit the scope of embodiments of the present disclosure to such example configurations.

In some aspects, in the following description, the hardware configuration and software configuration of the device, processing flow, manufacturing conditions, dimensions, materials, shapes, and other example implementation details are not intended to limit the scope of embodiments of the present disclosure to such an extent, especially unless specifically stated.

Embodiments of the present disclosure include an evaporation source device for forming a thin film on a deposited body by vapor deposition and a control method thereof, and the embodiments of the present disclosure can also be understood as a program that causes a computer to execute the control method or a storage medium storing the program.

The storage medium may be a non-transitory storage medium that can be read by a computer.

Embodiments of the present disclosure can be suitably applied to, for example, an apparatus that forms a thin film (material layer) with a desired pattern by vacuum deposition on the surface of a substrate, which is a vapor deposition target.

As the material of the substrate, any material such as, for example, glass, resin, or metal can be selected.

In some aspects, the deposited body of the film forming device is not limited to a flat substrate.

For example, a mechanical part with irregularities or openings may be used as a vapor deposition target.

In some aspects, embodiments of the present disclosure include selecting, as the deposition material, any material such as, for example, organic material or inorganic material (metal, metal oxide, or the like).

In some aspects, embodiments of the present disclosure support forming an organic film and a metal film.

Specifically, the technology in accordance with one or more embodiments of the present disclosure is applicable to manufacturing equipment for organic electronic devices (e.g., organic EL displays, thin film solar cells) and optical members.

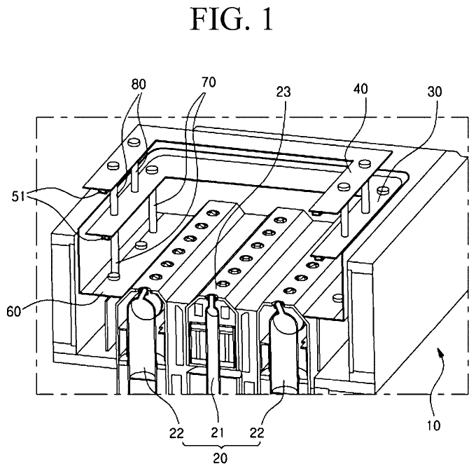

First, referring to FIG. 1, the main parts of a conventional display device deposition system that suppresses the increase in substrate/mask temperature will be described.

FIG. 1 is a schematic diagram of the main parts of a deposition system for a display device that suppresses a rise in substrate/mask temperature according to the prior art.

As illustrated in FIG. 1, the deposition system of a conventional display device has a process chamber 10 including a deposition source device 20 for thin film deposition arranged in a linear form, and the process proceeds continuously on the substrate. In this case, a double reflector consisting of a first reflector 30 and a second reflector 40 is formed around the deposition area above the deposition source device 20 away from the deposition source device 20.

In other words, the first reflector 30 is formed at a certain distance from the deposition source device 20, and the second reflector 40 is formed separately from the first reflector 30 on top of the first reflector 30. Unlike conventional cooling shields, the first reflector 30 and the second reflector 40 are not in contact with the deposition source device 20 but is formed at a certain distance, and the first reflector 30 and the second reflector 40 may aim to reflect and block convection and radiant heat transmitted from the deposition source, thereby suppressing the temperature rise of the substrate.

In some aspects, the first reflector 30 and the second reflector 40 are formed on the upper side of the deposition source device 20, and the first reflector 30 and the second reflector 40 are formed around the deposition area so as not to interfere with the movement of the deposition material sprayed from the deposition source.

Here, the deposition area refers to the area where the deposition material is sprayed with a certain kinetic energy from the deposition source, arrives at the substrate located on the opposite side and is deposited, and there is a path for the deposition material to reach the substrate.

In this way, rather than being installed in direct contact with the deposition source device 20 or the substrate to block heat or suppress the temperature rise of the substrate, the deposition area is formed to be spaced apart from the deposition source device 20 or the substrate, efficiently dissipating convection and radiant heat; the purpose is to suppress the temperature rise of the substrate by blocking it.

In some embodiments, the deposition source device 20 has a source 21 for providing a dopant material when depositing an organic thin film on a substrate, and a source 22 for providing a host material on both sides of the source 21, and a plurality of spray nozzles 23 may be formed or disposed on the upper side of the source to provide uniform dopant material and host material to the substrate from these sources.

The deposition source device 20 has a heating unit including a heater block to melt and vaporize the deposition material.

The first reflector 30 and the second reflector 40 are each formed in the shape of a square frame corresponding to the inner shape of the process chamber 10, and the middle portion must be formed so as not to interfere with the movement of the deposition material to the deposition area. In an example, the middle portion is in the form of a border formed around the deposition area. In some cases, the middle portion is in the form of a border formed only around the deposition area.

A cooling portion is further installed on the lower surface of one or both of the first reflector 30 and the second reflector 40, and the cooling portion is formed in the form of a cooling pipe 51 through which refrigerant can move, which effectively blocks the heat transmitted from the deposition source device 20.

Here, the term “refrigerant” refers to a substance or material that has a temperature capable of lowering the temperature of the first reflector 30 and the second reflector 40 to a degree that does not affect the deposition temperature of the deposition material, and may be water-cooled or air-cooled.

The deposition source device 20 is formed to entirely cover the source while exposing the injection nozzle 23, and the deposition source device 20 is formed with a cooling shield 60 formed of a plate to block heat from the source.

The cooling shield 60 is formed corresponding to the shape of the top part of the source, and it is formed in contact with or almost adjacent to the top of the source, thereby primarily blocking the heat transferred from the heat-generating part at the bottom of the source; it is formed of materials with low thermal conductivity, such as, for example, ceramics, stainless steel, double stainless steel, double aluminum alloy, or the like.

The first reflector 30 and the second reflector 40 are fixed to the upper side of the cooling shield 60. Specifically, the first reflector 30 is connected to the cooling shield by the first fixture 70, it is fixed and spaced apart from the cooling shield 60, and the second reflector 40 is formed by being fixed and spaced apart from the first reflector 30 by the second fixture 80.

According to the deposition system of the conventional display device illustrated in FIG. 1, the first reflector 30 and the second reflector 40 must be formed of a material with good illumination. In an example in which the cooling pipe 51 is installed at the bottom of each of the first reflector 30 and the second reflector 40, the first reflector 30 and the second reflector 40 are covered, and the cooling shield 60 must be fixed using the first fixture 70 and the second fixture 80 and the second reflector 40 are not only obscured, but there is a problem in that it is not easy to fix.

In some aspects, in the linear transfer deposition method according to some other approaches (e.g., as described with reference to FIG. 1), in order to prevent the substrate from contacting and damaging the mask during transport, a gap is maintained between the substrate and the mask during deposition, which must be perpendicular to the transport direction of the substrate (the direction perpendicular to the ground), it is good if all organic materials move in the same direction to form a normal pattern, but a case can be considered where they move outside the predetermined range due to the influence of the speed component of the substrate transfer direction and reach a place that is significantly deviated from the mask opening, the first reflector 30 and the second reflector 40 are unable to collect organic substances in this abnormal path, and the material accumulated on the first reflector 30 and the second reflector 40 falls and blocks the spray nozzle 23, or there is a problem in that organic materials can be contaminated.

In some aspects, the first reflector 30 and the second reflector 40 are formed to be spaced apart from the deposition source device 20 or the substrate to block convection and radiant heat to suppress the temperature rise of the substrate, but are limited to the periphery of the deposition area. Furthermore, the configuration may be less efficient in terms of heat shielding compared to heat conduction, which leads to direct and rapid cooling.

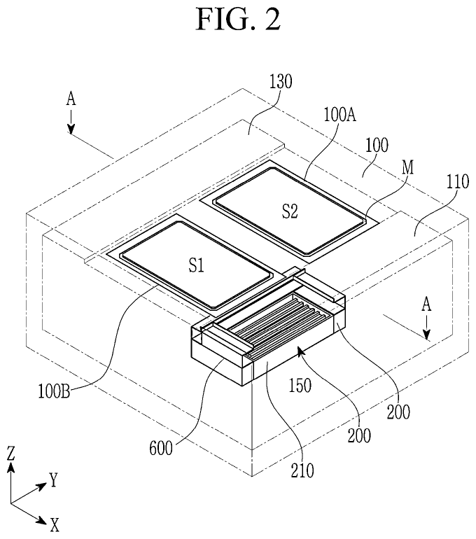

Now, with reference to FIGS. 2 to 5, a deposition system for a display device according to an embodiment supported by the present disclosure will be described.

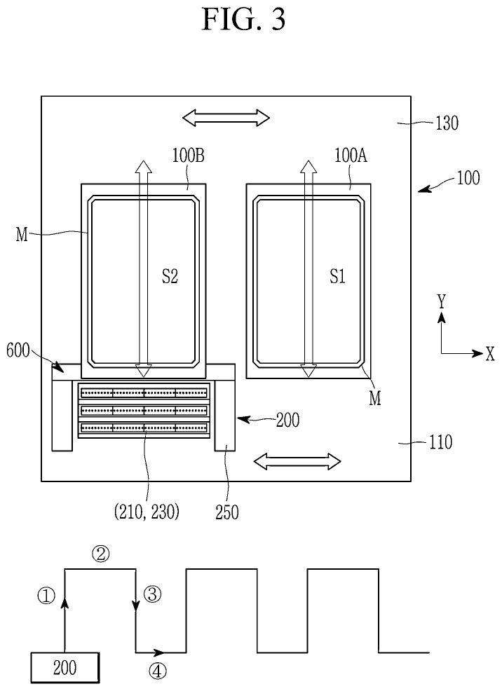

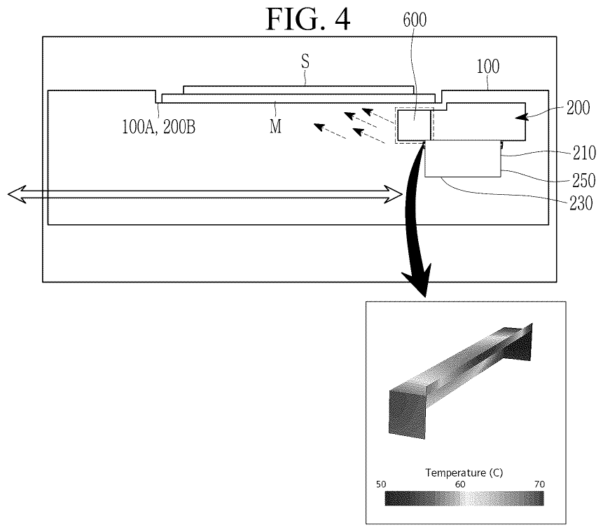

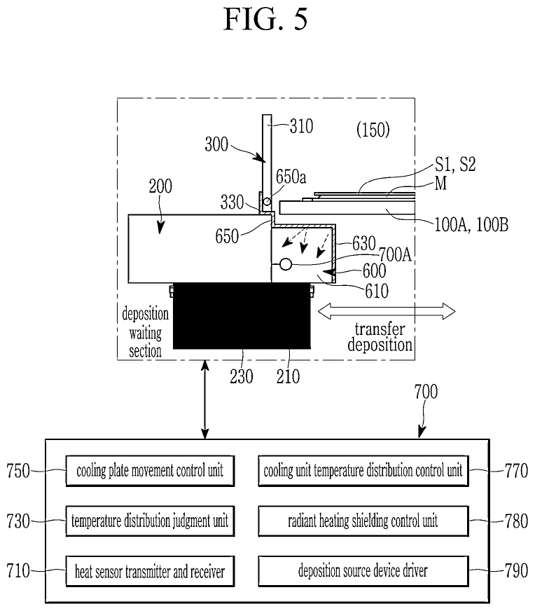

FIG. 2 is a schematic perspective view illustrating a deposition system for a display device according to an embodiment supported by the present disclosure, FIG. 3 is a cross-sectional view taken along line A-A of FIG. 2 and a diagram illustrating the temperature distribution near the substrate, FIG. 4 is a plan view illustrating a method of operating a main part of the deposition system of a display device according to an embodiment supported by aspects of the present disclosure, and FIG. 5 is a detailed view of the main part of FIG. 2.

As illustrated in FIG. 2 and FIG. 3, the deposition system 1 of a display device according to an embodiment supported by the present disclosure includes at least two substrates S1 and S2 in the deposition area section 150 disposed inside a process chamber 100 (also referred to herein as a deposition chamber), at least two substrate stages 100A and 100B are formed in this row and fixedly spaced apart from each other, and at least two substrates S1 and S2 and the mask M disposed below the at least two substrates S1 and S2 are in a stationary state.

Each substrate S (e.g., substrate S1, substrate S2) can be provided in an assembly form with the mask M, and the substrate S can be installed on the mask M frame. In some aspects, the substrate S may be fixed in place such that the substrate S does not move, which may reduce the risk of damage caused by contact with the mask M, and the reduction in the gap between the substrate S and the mask M may support precise pattern formation.

More specifically, since the at least two substrates S1, S2 may be fixed in relation to the deposition source device 200 in the deposition area section 150, embodiments of the present disclosure support refraining from installing the at least two substrates S1, S2 with a gap in relation to the mask M. This reduces the risk of damage to at least two substrates S1, S2 and the mask M, and prevents misalignment of at least two substrates S1, S2 and the mask M, allowing for the formation of highly precise normal patterns compared to conventional methods.

In the deposition area section 150 placed at the center of the process chamber 100, deposition standby sections 110, 130 are provided at both ends in the X-axis direction. In some aspects, the deposition source device 200 is kept on standby for a period of time while raising the temperature of the deposition sources 210, 230 to a state where the deposition process in the deposition standby sections 110, 130 is possible. Descriptions herein of a temperature and a state where the deposition process is possible may be referred to as a temperature supportive of the deposition process described herein or as a deposition-capable temperature.

As illustrated in FIG. 3, the deposition system 1 of the display device according to an embodiment supported by the present disclosure has the deposition source device 200 raise the temperature of the deposition sources 210 and 230 in the deposition standby sections 110 and 130. In an example in which it is confirmed through the heat distribution measurement unit 700A—that is, the temperature sensor or the thermal imaging camera 700A—that the temperature has been raised to a state in which the deposition process is possible, the deposition source device 200 operates in the deposition area section 150. That is, for example, the deposition source device 200 may perform at least the above 2 steps of depositing on the first substrate S1 among the at least two substrates (S1, S2) while moving in the deposition direction (Y-axis direction) of the first substrate S1 and the mask M among the above substrates (S1, S2).

The deposition source device 200 further includes a linear drive unit 250 consisting of a step motor and one or more other components supportive of features of the linear drive unit 250. The linear drive unit 250 may move in the deposition direction in the deposition area section 150 and be disposed perpendicular to the deposition area section 150. Embodiments of the present disclosure include performing a deposition process on the second substrate S2 by moving the linear drive unit 250 (and the deposition source device 200) in the X-axis direction in the deposition standby sections 110, 130.

In an example, the deposition source device 200 moves the deposition area section 150 in the Y-axis direction after waiting in the deposition standby sections 110, 130, moves in the X-axis direction in the deposition standby sections 110, 130, and then moves back to the Y-axis. A deposition film is formed on the at least two substrates (S1, S2) while moving in the Y-axis direction, which is opposite to the axial direction, using one deposition source device 200 to form the deposition film on the at least two substrates (S1, S2).

The deposition source device 200, as illustrated in FIGS. 3 and 4, can reduce the tact time by proceeding in a zigzag manner (as illustrated at FIG. 3) through the deposition standby sections 110, 130 and the deposition area section 150 in the order of \textcircled{1}, \textcircled{2}, \textcircled{3}, \textcircled{4}.

When forming a deposition film on a first substrate S1 of at least two substrates (S1, S2) on one of at least two stages (100A, 100B), a second substrate S2 is deposited on the other one.

As illustrated in FIG. 3, in the deposition standby sections 110, 130, the deposition source device 200 waits until the temperature of the deposition sources 210, 230 can be raised to a state where the process is possible; at this time, the temperature of the structures between the deposition source device 200 and at least two substrates S1 and S2 increases.

The deposition prevention unit 600 (cooling shield) disposed adjacent to the first substrate S1 among the at least two substrates S1 and S2 adjacent to the deposition source device 200 may be, for example, the deposition source device 200. Depending on its structure, it can be seen that the temperature rises unevenly to the level of 70° C. to 100° C. depending on the distance from the heating part.

The deposition system 1 of the display device according to an embodiment supported by the present disclosure heats a mask M or mask frame (MF; mask frame) where the first substrate S1 is seated, according to the radiated heat distribution confirmed through the above temperature sensor or thermal imaging camera 700A, and is characterized by installing a landing unit (e.g., deposition prevention unit 600) that can respond according to the heat transfer distribution to prevent the temperature of the first substrate S1 from rising, for at least two substrate stages 100A, 100B.

As illustrated in FIG. 5, in the deposition system for a display device according to an embodiment supported by the present disclosure, the temperature of the deposition sources 210 and 230 is raised to a state in which the process is possible in the deposition standby sections 110 and 130. In order to prevent uneven temperature rise of the first substrate S1 disposed adjacent to the deposition source device 200 due to radiant heat or convection heat from the deposition source device 200, a deposition prevention unit 600 (also referred to herein as a deposition blocking plate, a deposition prevention plate, or a barrier unit) disposed between the device 200 and the first substrate S1, interlocked with the deposition prevention unit 600, is attached to the first substrate S1. The deposition prevention unit 600 corresponds to heat transfer distribution and may include a cooling unit 300 that efficiently cools by direct thermal contact.

The deposition prevention unit 600 and the cooling unit 300 may be arranged to be offset with respect to respective center lines of the deposition prevention unit 600 and the cooling unit 300.

The deposition prevention unit 600 may include a deposition prevention space 610 (also referred to herein as a separated deposition prevention space or a spaced deposition prevention space) associated with preventing radiant heat or convective heat from the deposition source device 200 from being transferred to the first substrate S1. A radiant heat shielding plate part 630 (also referred to herein as a radiant heat shielding part) that forms the deposition prevention space 610 shields the radiant heat from the deposition source device 200, and directs the radiant heat towards the deposition source device 200, and a contact coupling part 650 (also referred to herein as a thermal contact coupling part) that allows direct or indirect thermal conduction through the process chamber 100 to the first substrate S1 or mask M or mask frame MF.

The contact coupling part 650 may be formed such that the contact coupling part 650 is attached to one end of the radiant heat shielding plate part 630. In some embodiments, the radiant heat shielding plate part 630 may be formed such that a deposition prevention space 610 forms a heat shielding space. It may be bent at 90 degrees, and in some embodiments, the contact coupling part 650 may be bent at 90 degrees with respect to the radiant heat shielding plate part 630.

The contact coupling part 650 is rotatable and movable at a predetermined angle with respect to a housing 200a of the deposition source device 200 through the hinge portion 650a.

The cooling unit 300 includes a cooling plate 310 located on top of the first substrate S1 that is fixedly placed. The cooling unit 300 includes a cooling plate coupling part 330 that couples the cooling plate 310 to the first and second substrate stages 100A, 100B around the first substrate S1.

The cooling plate coupling part 330 can be directly contact-coupled to the first substrate S1 or mask M or mask frame MF for heat conduction, and the heat from the deposition source device 200 can be deviated by more than 90 degrees from the edge of the first substrate S1 to minimize the thermal impact on the first substrate S1.

For this purpose, the cooling plate coupling part 330 may also have a hinge portion 330a.

Here, the deposition area section 150 refers to an area where there is a path for the deposition material to reach the substrate, which is located on the facing surface. The deposition material may be sprayed from the deposition source device 200 with a certain kinetic energy and be deposited on the substrate upon being incident the substrate.

In this way, the deposition source device 200 is installed in direct contact with the first substrate S1 or the mask M to block heat or suppress the temperature rise of the substrate (first substrate S1). At the same time, by forming a separation between the deposition source device 200 or the substrate, the cooling plate coupling part 330 supports suppression of the temperature rise of the substrate by efficiently blocking convection and radiant heat.

In some embodiments, the deposition source device 200 includes a source 210 for providing a dopant material when depositing an organic thin film on a substrate, and the deposition source device 200 includes a source 220 for providing a host material on both sides of the source 210. The deposition source device 200 may include a plurality of deposition sources 230 (e.g., spray nozzles) formed above (disposed above) the source 210 to provide uniform dopant material and host material to the substrate from the deposition sources 230.

The deposition source device 200 may be formed with a heating unit including a heater block to melt and vaporize the deposition material.

Therefore, according to an embodiment supported by the present disclosure, by the deposition system for the display device, the indirect convection and radiant heat transferred from the deposition source device 200 are reflected and blocked by the radiant heat shielding plate part 630 forming the deposition prevention space 610, thereby suppressing the temperature rise of the substrate. In some aspects, it is made to directly contact the process chamber 100 that accommodates the first substrate S1 or the mask M by the contact coupling part 650 in contact with the deposition source device and the cooling unit 300, thereby blocking the conductive heat directly transferred from the deposition source device 200 to further suppress the temperature rise of the substrate or mask.

The inside of the process chamber 100 is maintained in a vacuum atmosphere or an inert gas atmosphere such as, for example, nitrogen gas.

The least two substrates S1, S2 are held and supported by the substrate stages 100A, 100B after being transported into the process chamber 100 by the transport robot (not illustrated), and are fixed to be parallel to the horizontal XY plane during the film formation.

The mask M is a mask with an opening pattern corresponding to a thin film pattern of a certain pattern formed on the first and second substrates (S1, S2), for example, during the formation of a deposition film with a metal mask, the substrate is placed on the mask M.

In some embodiments, as illustrated in FIG. 5, the deposition system 1 of the display device according to an embodiment supported by the present disclosure has a temperature at which the deposition source device 200 can deposit the deposition source in the deposition standby sections 110 and 130. The heat influence distribution on the first substrate S1 or the mask M during elevation is confirmed through the temperature sensor or thermal imaging camera 700A, and the deposition prevention unit 600 or the cooling unit 300. The deposition system 1 further includes a cooling control device 700 that communicates and controls the temperature sensor or thermal imaging camera 700A, the deposition prevention unit 600, or the cooling unit 300 to enable control.

The cooling control device 700 includes a temperature sensor control unit 710 configured to control measurement of the temperature sensor or thermal imaging camera 700A and transmits and receives measurement data, and a temperature distribution measured by the temperature sensor control unit 710, a heat distribution determination unit 730 (also referred to herein as a thermal impact distribution determination unit) that determines the thermal impact distribution for the first substrate S1 or the mask M, and the first substrate S1 determined by the heat distribution determination unit 730. In some aspects, the cooling control device 700 includes a cooling plate movement control unit 750 configured to control the movement of the cooling plate of the cooling unit 300 in order to efficiently reduce the heat influence distribution on the mask M and efficiently reduce the temperature of the cooling portion installed in the cooling plate 310. Furthermore, the cooling control device 700 contains a cooling unit temperature distribution control unit 770 configured to control the distribution, a radiant heat shielding control unit 780 configured to control rotation of the radiant heat shielding plate part 630 (e.g., control the radiant heat shielding plate part 630 to rotate at a predetermined angle such that the radiant heat shielding plate part 630 can collect the deposition source and effectively shield the radiant heat). The cooling control device 700 may include a deposition source device driver 790 (also referred to herein as a deposition source device movement control section) configured to control zigzag movement between the deposition standby sections 110 and 130 and the deposition area section 150 of the deposition source device 200.

The deposition source device driver 790 can operate the aforementioned deposition source device 200 within the process chamber 100 at a speed that minimizes thermal effects on the first substrate S1 or mask M.

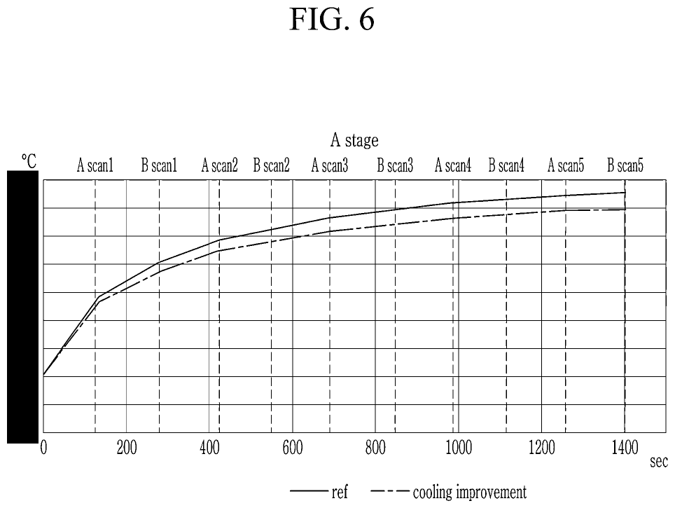

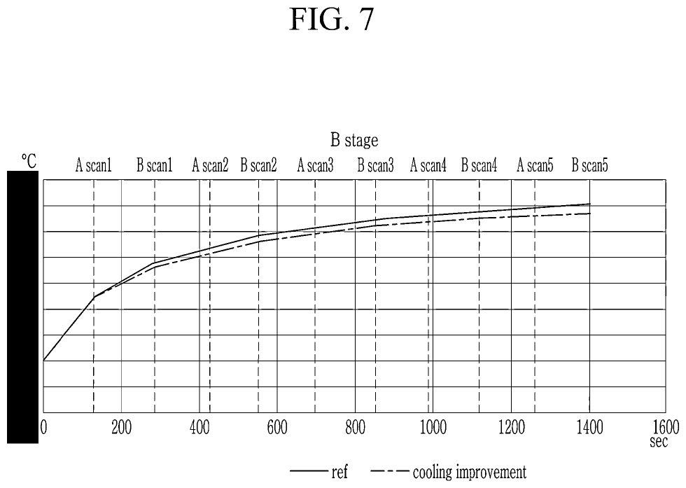

FIG. 6 and FIG. 7 are diagrams illustrating the cooling improvement effect in substrate stages A and B, respectively, of the deposition system of the display device according to an embodiment supported by the present disclosure.

As illustrated in FIG. 6, when reciprocating a total of 5 deposition area sections after the deposition standby period in stage A, in the conventional method, the deposition prevention unit 600 around the deposition sources 210 and 230 is connected to the deposition sources 210 and 230 and is heated due to radiant heat, which becomes a factor in raising the temperature of the substrate S or mask M. However, in accordance with one or more embodiments of the present disclosure, the techniques described herein may include using the deposition prevention unit 600 and the cooling unit 300 to heat the substrate S. Alternatively, it can be seen that the mask M is disposed in response to the heat influence distribution and provides heat shielding to reduce the temperature of the mask during the deposition process.

Likewise, as illustrated in FIG. 7, in stage B adjacent to stage A, when reciprocating a total of five deposition area sections after the deposition standby period, in the conventional method, the deposition prevention unit 600 around the deposition sources 210 and 230 heats up due to radiant heat from the deposition sources 210 and 230, which causes the temperature of the substrate S or the mask M to rise. However, in accordance with one or more embodiments of the present disclosure, the deposition prevention unit 600 and the cooling unit 300 are arranged based on the heat influence distribution of the substrate S or mask M to provide heat shielding and reduce the temperature of the mask during the deposition process.

In both FIGS. 6 and 7, the effect was verified using thermal analysis.

As a result of simulating the deposition process for five substrates, it was confirmed that the temperature of the substrate or mask gradually decreased compared to the conventional method as the deposition process continued.

Therefore, during mass production, after the deposition process of a predetermined quantity of substrates (e.g., 50 to 60 substrates), it is recommended to replace the mask M and reset the temperature of the cooling unit 300 or deposition prevention unit 600 in the process chamber 100 by using at least two substrates (S1, S2) and the thermal effect of the mask M can be prevented. This process allows the formation of a high-precision normal pattern. In some examples, resetting the temperature of the cooling unit 300 or deposition prevention unit 600 may include powering off the deposition source device 200 (e.g., based on one or more criteria).

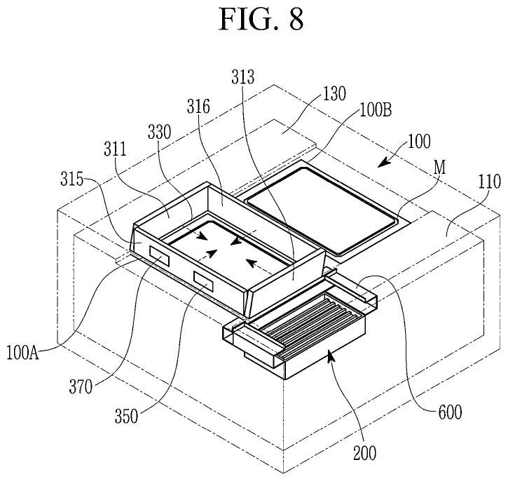

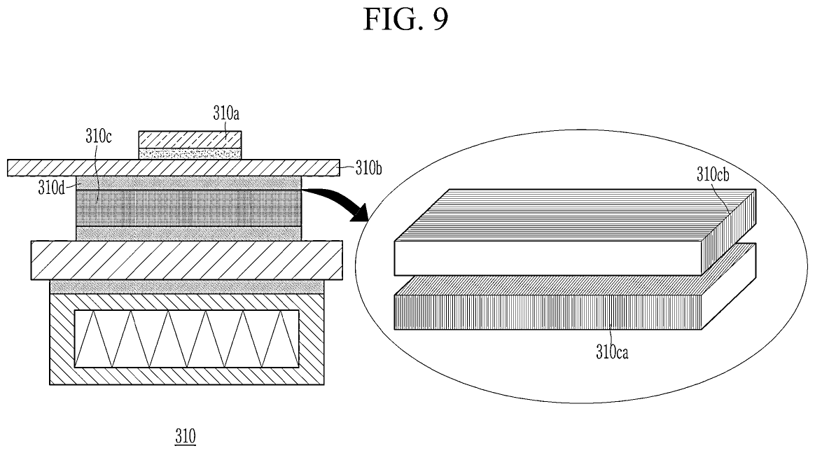

Now, a deposition system for a display device according to a modified example in accordance with one or more embodiments of the present disclosure will be described with reference to FIGS. 8 and 9.

FIG. 8 is a perspective view of a deposition system for a display device according to a modified example in accordance with one or more embodiments of the present disclosure, and FIG. 9 is a diagram illustrating the structure of the cooling plate 310 of FIG. 8.

The deposition system 1′ of the display device according to a modification example in accordance with one or more embodiments of the present disclosure, like the deposition system 1 of the display device according to an embodiment supported by the present disclosure, includes a deposition source device 200, and a first substrate S1 between which is placed a deposition prevention unit 600. A cooling unit 300 that is linked with the deposition prevention unit 600 corresponds to the heat transfer distribution on the first substrate SI from above the first substrate S1, and directly contacts the substrate to cool it efficiently.

In some aspects, the deposition prevention unit 600 includes a deposition prevention space 610 to prevent radiant or convective heat from being transferred from the deposition source device 200 to the first substrate S1, and the deposition source device 200, a radiant heat shielding plate part 630 that shields radiant heat from 200 and directs radiant heat toward the deposition source device 200, and on the first substrate S1 or mask M or mask frame MF, and it includes a contact coupling part 650 that is contact-coupled to conduct heat directly or directly through the process chamber 100.

The above cooling unit 300 includes a cooling plate 310 placed on top of a first substrate S1 that is fixedly arranged, and a cooling plate coupling part 330 that couples the cooling plate 310 to the first and second substrate stages (100A, 100B) around the first substrate S1.

The deposition system 1′ of a display device according to a modified example in accordance with one or more embodiments of the present disclosure installs the cooling plate 310 on all sides of the first substrate S1 through the cooling plate coupling part 330, it may include a pair of first and second cooling plates 311 and 313 for the short sides of the first substrate S1 and a pair of third and fourth cooling plates 315 and 316 for the long sides, they are installed like a barrier in the height direction, and they are installed at a predetermined angle, preferably 90 degrees or more.

In some aspects, the deposition system 1′ of the display device according to a modified example in accordance with one or more embodiments of the present disclosure has a local cooling pipe along the lower part of the cooling plate 310 for a portion in thermal contact with the substrate S or mask M, and a cooling plate coupling part 330 (e.g., a cooling pipe, a cooling tube) may further be included.

A cooling liquid for selectively and intensively cooling a local portion in thermal contact with the substrate S or the mask M may flow through the cooling plate coupling part 330.

The coolant may be water, alcohol, or any evaporable liquid.

The cooling plate coupling part 330 has an input end and an output end, and the cooling liquid in the cooling plate coupling part 330 flows from the input end to the output end along the cooling plate coupling part 330, and the output end is connected to a circulation pump 350 for circulation, it can be controlled, and a radiator or other type of heat exchanger 370 can be installed in the circulation pump 350 to help dissipate coolant heat.

The process chamber 100 is a container that forms a space for vacuum deposition, and when the deposition source device 200 performs deposition, the inside of the process chamber 100 is evacuated (depressurized) by a vacuum pump to at least allow deposition. During the period, it is maintained in a high vacuum state (e.g., achieved vacuum: 1×10² Pa or less).

The deposition source device 200 is controlled by the deposition source device driver 790 to move linearly in the X-axis and Y-axis directions by the linear movement mechanism. The linear movement mechanism may include, for example, a straight guide extending in the Y-axis direction, a ball screw extending in the Y-axis direction, a ball nut screwed to the ball screw, a drive motor (electric motor) such as, for example, a servo motor, stepping motor, or the like that rotates the ball screw, and a motor drive control section electrically connected to the drive motor.

In some embodiments, as illustrated in FIG. 9, the cooling plate 310 connects a thermal contact member 310a coupled to the periphery of the substrate S or the mask M, and heat conducted from the thermal contact member 310a; it can be formed by combining the heat diffusion member 310c using heat conductive grease 310d.

A heat exchanger coupled to the thermal contact member 310a through a lead wire 310b may be added to the heat diffusion member 310c through an electrical insulating layer.

The heat diffusion member 310c is composed of at least two layers, and heat diffusion plates 310ca and 310cb in different directions may be stacked.

The heat diffusion member 310c can be formed by stacking and integrating thin plates made entirely of graphite.

In this specification, the types of the deposition sources 210 and 230 are not particularly limited and may be, for example, a point deposition source (point source), a line deposition source (line source), or a surface deposition source.

In some aspects, the heating method of the deposition sources 210 and 230 is not particularly limited and includes, for example, resistance heating, electron beam, laser deposition, high-frequency induction heating, and arc methods.

In some aspects, the arrangement of the nozzles is not particularly limited; for example, multiple rows of nozzles may be arranged in the Y-axis direction.

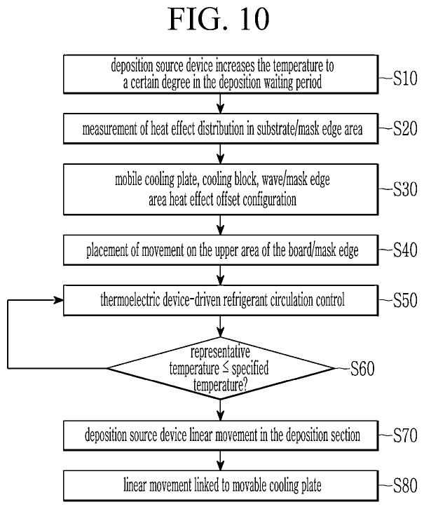

Now, a deposition method for a display device according to an embodiment supported by the present disclosure will be described with reference to FIG. 10.

FIG. 10 is a flowchart of a deposition method for a display device according to an embodiment supported by the present disclosure.

Hereinafter, a deposition method for a display device according to an embodiment supported by the present disclosure will be described based on a deposition system for a display device according to an embodiment supported by the present disclosure for a light emitting layer deposition process for a display device.

In the light emitting layer deposition process, the method may include reducing the pressure inside the process chamber 100 and placing the process chamber 100 into a high vacuum state (e.g., achieved vacuum: 1×10⁻² Pa or less).

At S10, the method may include placing a deposition source device 200 in the deposition standby sections 110, 130 within the process chamber 100, filling the deposition sources 210, 230 of the deposition source device 200 with material, and heating the deposition sources 210, 230 (and/or the material) to a predetermined temperature at which deposition is possible. In some aspects, at S10, the deposition source device 200 may increase the temperature of the deposition sources 210, 230 (and/or the deposition material) to a certain degree in the deposition standby section 110, during a deposition waiting period.

At S20, the method may include introducing the first substrate SI into the process chamber from the introduction port (not illustrated) such that the first substrate S1 is supported on the substrate stage 110A, and measuring the thermal impact distribution on the first substrate SI or the mask edge area under the first substrate SI using a temperature sensor or a thermal imaging camera 700A. The method may include transmitting the thermal impact distribution on the mask edge area to the temperature sensor control part 280 of the cooling control device 700 for data processing. In some aspects, at S20, the method may include measuring heat effect distribution in a substrate/mask edge area.

At S30, the method may include designing a thermal effect distribution offset cooling design (also referred to herein as configuring a thermal effect distribution offset) to offset the thermal effects on the first substrate S1 or mask M by selectively controlling the supply of coolant to the cooling plate coupling part 330 installed in the cooling plate 310 of the cooling unit 300 that is in thermal contact with the first substrate S1 or mask M around the first substrate S1. Additionally, or alternatively, at S30, the method may include designing the thermal effect distribution offset cooling design by selectively controlling the arrangement of the cooling plate 310. In some aspects, at S30, the method may include configuring a mobile cooling plate (e.g., cooling plate 310), a cooling block, and a wave/mask edge area heat effect offset.

At S40, the method may include moving the cooling plate 310 and installing the cooling plate 310 around the first substrate SI or the mask M according to the heat effect distribution offset cooling design. In some aspects, at S40, the method may include placement of movement on the upper area of the board/mask edge.

At S50, the method may include selectively controlling the circulation of coolant in the cooling plate coupling part 330 within the cooling plate 310. In some aspects, at S50, the method may include controlling refrigerant circulation, in which the control is thermoelectric-device driven.

At S60, the method may include determining whether the representative temperature measured by the temperature sensor 700A around the first substrate S1 is below a predetermined temperature. Based on determining the representative temperature is below the predetermined temperature, the method may include proceeding to S70. In some aspects, at S60, the method may include comparing the representative temperature to the predetermined temperature (also referred to herein as a specified temperature).

At S70, the method may include performing deposition on the first substrate S1 by linearly moving the deposition source device 200 in the deposition area section 150. In some aspects, at S70, the method may include controlling linear movement of the deposition source device 200 in the deposition area section 150 (also referred to herein as deposition section).

According to the deposition source device driver 790 configured to control the deposition source device driver 270 of the deposition source device 200, the driving speed and direction of the deposition source device driver 270, and the deposition standby section (110, 130) and the deposition area section 150 repeatedly move linearly. Expressed another way, at S70, the method may include repeatedly moving the deposition source device 200 linearly in the deposition standby sections 110, 130 and the deposition area section 150.

The method may include moving the cooling plate 310 of the cooling unit 300 in response to the movement of the heat influence distribution corresponding to the driving speed transmitted from the deposition source device driver 790 configured to control the deposition source device driver 270. In some aspects, at S80, the method may include selectively controlling the supply of refrigerant flowing through the cooling plate coupling part 330 installed inside the cooling plate 310. In some aspects, at S80, the method may include linearly moving the deposition source device 200, in which the linear movement is linked to the cooling plate 310 (movable cooling plate).

In accordance with one or more embodiments of the present disclosure, the method may include continuously performing the deposition on the first substrate SI on the second substrate S2 for a threshold quantity of sheets (e.g., a maximum of 50 to 70 sheets), in accordance with the operation speed of the deposition source device 200 for the first substrate S1, such that the heat effect distribution is maintained uniformly.

The method may include, while the deposition source device 200 moves at a constant speed along the Y-axis with respect to the first substrate SI or the mask M, discharging (by the deposition source device 200) the deposition material such that the deposition material passes through the mask opening in the deposition area of the first substrate S1, and particles can attach one after another to form a stripe-shaped pattern (deposited film).

After the first deposition, the method may include linearly moving the deposition source device 200 in the X-axis direction, and the method may include performing the second deposition in the same manner as the first deposition.

Specifically, the deposition particles are attached to the deposition area (however, the area in which the pattern was not formed by the first deposition) of the first substrate S1 while the deposition source device 200 moves at a constant speed in the direction opposite to the movement direction associated with the first deposition to form a stripe-shaped pattern (deposited film).

As a result, a stripe-shaped pattern of the light emitting layer is formed throughout the deposition area of the first substrate S1.

In some aspects, the method may include performing the deposition described herein multiple times over multiple iterations in association with achieving a pattern thickness which is equal to or greater than a desired layer thickness.

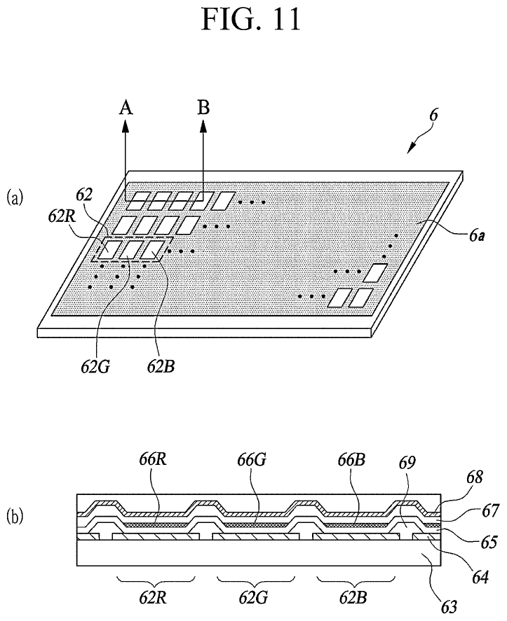

FIG. 11 is a plan view and a cross-sectional view of a display device manufactured using a deposition system and method according to an embodiment supported by the present disclosure.

As illustrated in FIG. 11(a), the display device 6 may be an organic electroluminescent display device, and in the display area 61, a plurality of pixels 62 having a plurality of light emitting devices are arranged in a matrix shape.

Details will be explained below, but each light emitting element has a structure including an organic layer sandwiched between a pair of electrodes.

In some aspects, the term “pixel” refers to the minimum unit that enables display of a desired color in the display area 61.

In the case of the organic electroluminescent display device according to this embodiment, the pixel 62 is formed by a combination of the first light emitting device 62R, the second light emitting device 62G, and the third light emitting device 62B that emit different light.

In some aspects, the pixel 62 may be composed of a combination of red, green, and blue light emitting devices, but is not limited thereto. For example, the pixel 62 may be a combination of yellow, cyan, and white light emitting devices, but is not limited thereto. The pixel 62 is not particularly limited to the examples described herein, and the pixel 62 may include light emitting devices of at least one color or more.

As illustrated in FIG. 11(b), the pixel 62 includes a first electrode (anode) 64, a hole transport layer 65, and light emitting layers 66R, 66G, and 66B on a substrate 63; it has an organic electroluminescent element including any one of them, an electron transport layer 67, and a second electrode (cathode) 68.

Among these, the hole transport layer 65, the light emitting layers 66R, 66G, and 66B, and the electron transport layer 67 correspond to the organic layer.

In some aspects, in this embodiment, the light emitting layer 66R is an organic electroluminescent layer that emits red light, the light emitting layer 66G is an organic electroluminescent layer that emits green light, and the light emitting layer 66B is an organic electroluminescent layer that emits blue light.

The light emitting layers 66R, 66G, and 66B are formed in a pattern corresponding to light emitting devices (sometimes referred to as organic electroluminescent elements) that emit red light, green light, and blue light, respectively.

In some aspects, the first electrode 64 is formed separately for each light emitting device.

The hole transport layer 65, the electron transport layer 67, and the second electrode 68 may be formed in common with the plurality of light emitting devices 62R, 62G, and 62B, or may be formed for each light emitting device.

In some aspects, to prevent the first electrode 64 and the second electrode 68 from being short-circuited by foreign substances, an insulating layer 69 is provided between the first electrode 64.

In some aspects, since the organic electroluminescent layer is deteriorated by moisture and oxygen, a protective layer 70 is provided to protect the organic electroluminescent element from moisture and oxygen.

Embodiments supported by the present disclosure will now be described more fully hereinafter with reference to the accompanying drawings, in which one or more example embodiments are illustrated. Aspects supported by the present disclosure may, however, be embodied in different forms and should not be construed as limited to the embodiments set forth herein. Rather, these example embodiments are provided so that this disclosure will be thorough and complete, and will fully convey the scope of example aspects of the invention to those skilled in the art.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases.

It is to be understood that if an element (e.g., a first element) is referred to, with or without the term “operatively” or “communicatively”, as “coupled with”, “coupled to”, “connected with”, or “connected to” another element (e.g., a second element), it means that the element may be coupled with the other element directly (e.g., wiredly), wirelessly, or via a third element.

What is claimed is:

1. A deposition system for a display device, comprising:
a process chamber comprising a deposition area section and deposition standby sections, wherein the deposition area section is disposed between the deposition standby sections;
a deposition source device for thin film deposition, wherein the deposition source device is movably installed between the deposition standby sections and a substrate stage, wherein a substrate installed on the substrate stage is above the deposition area section and is arranged in a linear form;
a deposition prevention unit disposed between the deposition source device and the substrate installed on the substrate stage; and
a cooling unit which is interlocked with the deposition prevention unit and is directly coupled to a periphery of the substrate, wherein the cooling unit protrudes upward,
wherein the deposition system for the display device is configured to continuously perform a deposition process on at least two substrates arranged in a linear direction in the process chamber, wherein the at least two substrates comprise the substrate installed on the substrate stage.

2. The deposition system of claim 1, further comprising:
a heat effect distribution measurement unit closely coupled to the substrate or a second substrate and configured to measure a heat effect distribution around a mask while raising a temperature of a deposition source comprised in the deposition source device to a deposition-capable temperature; and
a cooling control device configured to control the deposition prevention unit or the cooling unit based on a heat influence distribution measured by the heat effect distribution measurement unit.

3. The deposition system of claim 2, wherein:
the deposition prevention unit comprises:
a spaced deposition prevention space for preventing radiant heat or convection heat from being transferred to the substrate or the second substrate from the deposition source device, and a radiant heat shield forming the spaced deposition prevention space.

4. The deposition system of claim 3, wherein:
the deposition prevention unit comprises a contact coupling part configured to directly contact a peripheral portion of the substrate or the mask in association with conducting heat,
wherein the contact coupling part is configured to pivot the radiant heat shield in association with varying a size of the spaced deposition prevention space.

5. The deposition system of claim 2, wherein:
the cooling unit comprises:
a cooling plate disposed such that the cooling plate protrudes upward from a periphery of the substrate or the mask; and
a cooling plate coupling unit configured to detachably couple the cooling plate to the periphery of the substrate or the mask in an assembly manner.

6. The deposition system of claim 5, wherein:
an angle between the cooling plate and a periphery of the substrate or the mask is equal to 90 degrees or more.

7. The deposition system of claim 2, wherein:
the heat effect distribution measurement unit is a thermal imaging camera or a temperature sensor configured to measure a representative temperature of an area with a highest temperature in the deposition area among a periphery of the substrate or the mask.

8. The deposition system of claim 2, further comprising:
a cooling plate comprising:
a local cooling pipe, wherein the local cooling pipe is in thermal contact with a bottom portion of a periphery of the substrate or the mask; and
a circulation pump configured to circulate refrigerant flowing inside the local cooling pipe.

9. The deposition system of claim 8, wherein:
the cooling plate comprises:
a thermal contact member thermally contacting a peripheral portion of the substrate or the mask; and
a heat diffusion member configured to diffuse heat from the thermal contact member.

10. The deposition system of claim 9, wherein:
the heat diffusion member is formed in two layers of a plurality of heat diffusion plates in different directions, and the heat diffusion member is disposed on all sides of the substrate or the mask.

11. The deposition system of claim 10, wherein:
the deposition system is configured to adhere the thermal contact member and the heat diffusion member by applying a thermally conductive grease as an adhesive between the thermal contact member and the heat diffusion member.

12. The deposition system of claim 1, wherein:
the display device is an organic electroluminescent display device and the deposition process is a light emitting layer deposition process.

13. A deposition method for a display device, comprising:
continuously performing a set of operations on at least two substrates arranged in a linear form in a process chamber comprising a deposition source device for thin film deposition, wherein the set of operations comprise:
measuring, by a heat distribution measurement unit, a temperature of a surrounding area of a substrate while heating a deposition source of the deposition source device to a deposition-capable temperature in a deposition standby section;
determining a heat influence distribution on the substrate or a mask based on measurement results provided by the heat distribution measurement unit;
designing a cooling unit on top of the substrate or the mask in association with reducing the heat influence distribution on the substrate or the mask;
installing or controlling the cooling unit in association with reducing the heat influence distribution; and
performing a thin film deposition operation on the substrate while moving the deposition source device from the deposition standby section to a deposition area section.

14. The deposition method of claim 13, wherein:
the deposition method for the display device is a deposition process for a light emitting layer of an organic electroluminescent display device.

15. A deposition method for a display device, comprising:
arranging a deposition source device in a deposition standby section within a process chamber;
heating a deposition source of the deposition source device in association with increasing a temperature of the deposition source to a deposition-capable temperature;
fixing and installing a substrate on a substrate stage above the deposition source device;
measuring heat influence distribution around the substrate or a lower mask of the substrate;
performing a heat effect distribution offset cooling design for a heat effect distribution of a cooling unit in thermal contact with the substrate or the lower mask of the substrate; and
performing a thin film deposition process by driving the deposition source device on the substrate or the lower mask of the substrate.

16. The deposition method of claim 15, wherein:
measuring, by a heat effect distribution measurement unit, a representative temperature of an area with a highest temperature in a deposition area among the substrate or a surrounding area of the lower mask,
wherein the heat effect distribution measurement unit is a thermal imaging camera or a temperature sensor.

17. The deposition method of claim 15, wherein:
the performing the heat effect distribution offset cooling design comprises forming a barrier such that a cooling plate of the cooling unit protrudes upward at an angle of 90 degrees or more on all sides of the substrate or the lower mask.

18. The deposition method of claim 15, comprising:
moving a cooling plate of the cooling unit along a linear movement direction of the deposition source device and selectively controlling a supply of coolant flowing to a local cooling pipe installed inside the cooling plate.

19. The deposition method of claim 15, further comprising:
performing deposition on the substrate by alternately moving the deposition source device back and forth among a deposition area section and a deposition standby section formed at both edges of the deposition area section.

20. The deposition method of claim 15, further comprising:
powering off the deposition source device to reset the temperature during a deposition standby period based on processing a predetermined quantity of substrates.
